(19) United States
(12) Patent Application Publication
(10) Pub. No.: US 2025/0366084 A1
(43) Pub. Date: Nov. 27, 2025

(54) DIODE TRENCH ISOLATION FOR IMPROVED BREAKDOWN VOLTAGE UNIFORMITY

(71) Applicant: Texas Instruments Incorporated, Dallas, TX (US)

(72) Inventors: Kartikey Thakar, Bangalore (IN); Sunglyong Kim, Allen, TX (US); Yeguang Zhang, Chengdu (CN); Tian Ping Lv, Chengdu (CN); Yuanchun Wu, Chengdu (CN)

(21) Appl. No.: 18/671,819

(22) Filed: May 22, 2024

(51) Int. Cl. H01L 29/06; H01L 21/265; H01L 21/266; H01L 21/3065; H01L 21/308; H01L 23/31; H01L 23/495; H01L 29/66; H01L 29/866

(52) U.S. Cl. CPC H10D 62/104; H01L 21/26513; H01L 21/266; H01L 21/3065; H01L 21/308; H01L 23/3107; H01L 23/49531; H01L 23/49562; H10D 8/022; H10D 8/25

(57) ABSTRACT

A semiconductor device includes a semiconductor layer over a semiconductor substrate with adjacent first and second portions, the first portion having a first conductivity type, and the second portion having a second, opposite, conductivity type, and an isolation trench extending through first and second portions and laterally surrounding the first and second portions of the semiconductor layer. A method includes implanting dopants of a first conductivity type in a first portion of a semiconductor layer, implanting dopants of a second, opposite, conductivity type in a second portion of the semiconductor layer that is adjacent to the first portion, and forming an isolation trench that extends through and laterally surrounds the first and second portions to form a junction between the interior portions of the first and second portions within the isolation trench that is approximately planar.

### BACKGROUND

Junction diodes and Zener diodes are used in semiconductor devices for a variety of circuit applications. The breakdown voltage rating of a diode ensures suitability for operation in a given system. The p-n junction in a semiconductor layer impacts the diode breakdown voltage. However, curves at cylindrical and spherical junctions at the edges of implant boundaries of implanted p and n regions can reduce the diode breakdown voltage performance compared to parallel plane junctions. Floating field rings and/or field plates can be provided above the curved edges of the implanted regions to help control diode breakdown voltage performance, but these add significant area that does not contribute to the active device operation, and can therefore inhibit the ability to reduced device size and increase power density, etc.

### SUMMARY

In one aspect, a semiconductor device includes a semiconductor layer over a semiconductor substrate and having adjacent first and second portions. The first portion of the semiconductor layer has a first conductivity type and includes a first node, and the second portion of the semiconductor layer has a second, opposite, conductivity type and includes a second node. An isolation trench extends through the first and second portions of the semiconductor layer and laterally surrounds the first and second nodes.

In another aspect, a system includes a circuit board with conductive features, as well as a semiconductor device having a package structure, a semiconductor die enclosed by the package structure, and conductive leads partially enclosed by the package structure and soldered to respective ones of the conductive features of the circuit board. The semiconductor die includes a semiconductor layer over a semiconductor substrate and having adjacent first and second portions. The first portion of the semiconductor layer has a first conductivity type and includes a first node, and the second portion of the semiconductor layer has a second, opposite, conductivity type and includes a second node. An isolation trench extends through the first and second portions of the semiconductor layer and laterally surrounds the first and second nodes.

In a further aspect, a method of fabricating a semiconductor device includes implanting dopants of a first conductivity type in a first portion of a semiconductor layer, implanting dopants of a second, opposite, conductivity type in a second portion of the semiconductor layer that is adjacent to the first portion, and forming an isolation trench that extends through the first and second portions of the semiconductor layer and laterally surrounds a first node of the first portion and a second node of the second portion to form a junction between the first and second nodes within the isolation trench that is approximately planar.

### BRIEF DESCRIPTION OF THE DRAWINGS

FIG. 1 is a partial sectional side elevation view of a semiconductor device taken along line 1-1 of FIG. 1A having oppositely doped implanted regions and a trench surrounding a first node and a second node of a diode with a planar junction, a top side connection and a bottom side connection.

FIG. 1A is a partial sectional top plan view of the semiconductor device taken along line 1A-1A a of FIG. 1.

FIG. 1B is a partial sectional side elevation view of a system with the semiconductor device mounted to a circuit board.

FIG. 1C is a top view of an implementation of the semiconductor device having a small outline diode (SOD) package.

FIG. 2 is a flow diagram of a method of fabricating a semiconductor device.

FIGS. 3-14 are partial sectional side elevation views of the semiconductor device of FIGS. 1-1C undergoing fabrication processing according to the method of FIG. 2.

FIG. 15 is a partial sectional side elevation view of another semiconductor device having oppositely doped implanted regions and a trench surrounding an anode and a cathode of a diode with a planar junction, a top side anode connection, a bottom side cathode connection and a buried layer.

FIG. 16 is a partial sectional side elevation view of another semiconductor device having oppositely doped implanted regions and a trench surrounding an anode and a cathode of a diode with a planar junction, a top side cathode connection, a bottom side anode connection and a buried layer.

FIG. 17 is a partial sectional side elevation view of an integrated circuit semiconductor device having oppositely doped implanted regions and a trench surrounding an anode and a cathode of a diode with a planar junction, top side anode and cathode connections and a buried layer.

FIG. 18 is a partial sectional side elevation view of another semiconductor device taken along line 18-18 of FIG. 18A having oppositely doped implanted portions and an array of isolation trenches surrounding respective portions and planar p-n junctions.

FIG. 18A is a top plan view of the semiconductor device of FIG. 18.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/-10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various disclosed structures and methods may be beneficially applied to manufactured semiconductor devices electronic apparatus such as an integrated circuit or other electronic device. While such examples may be expected to provide various improvements, no particular result is a requirement of the present disclosure unless explicitly recited in a particular claim.

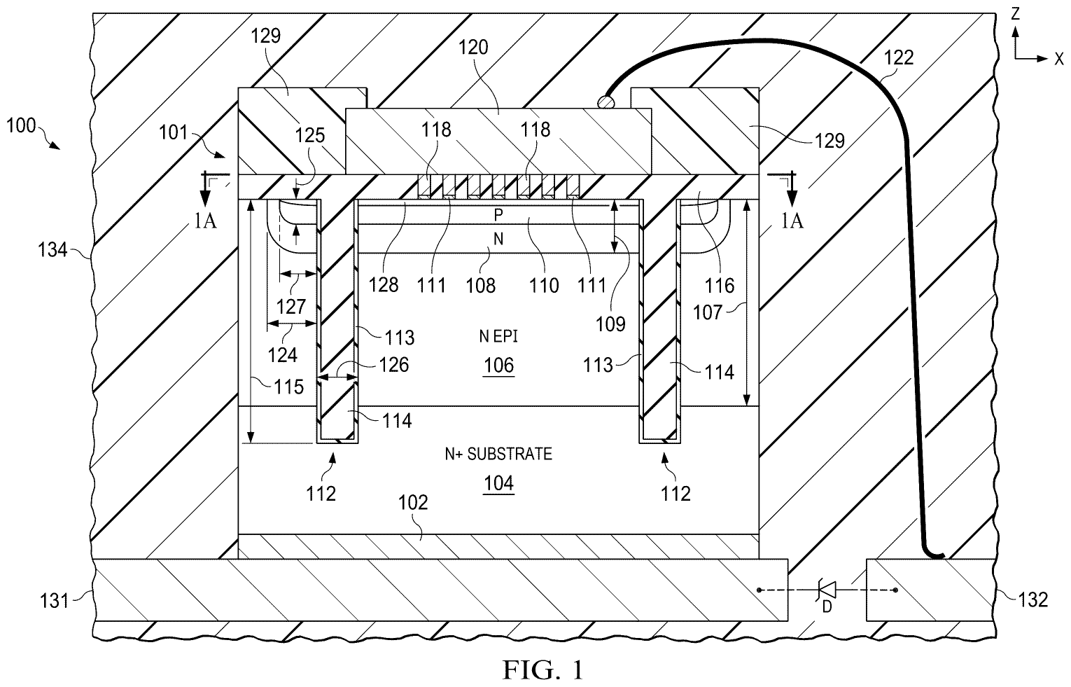

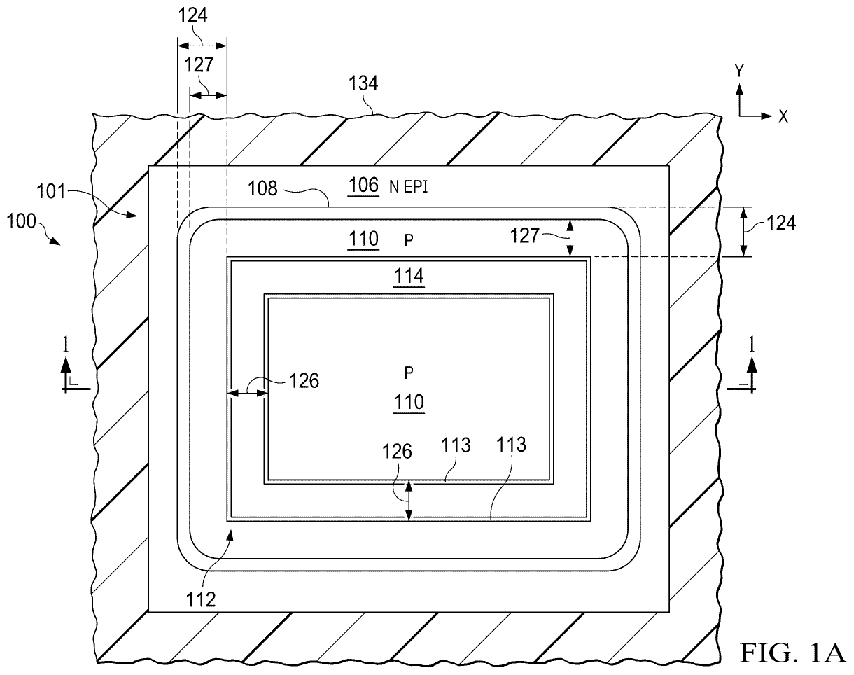

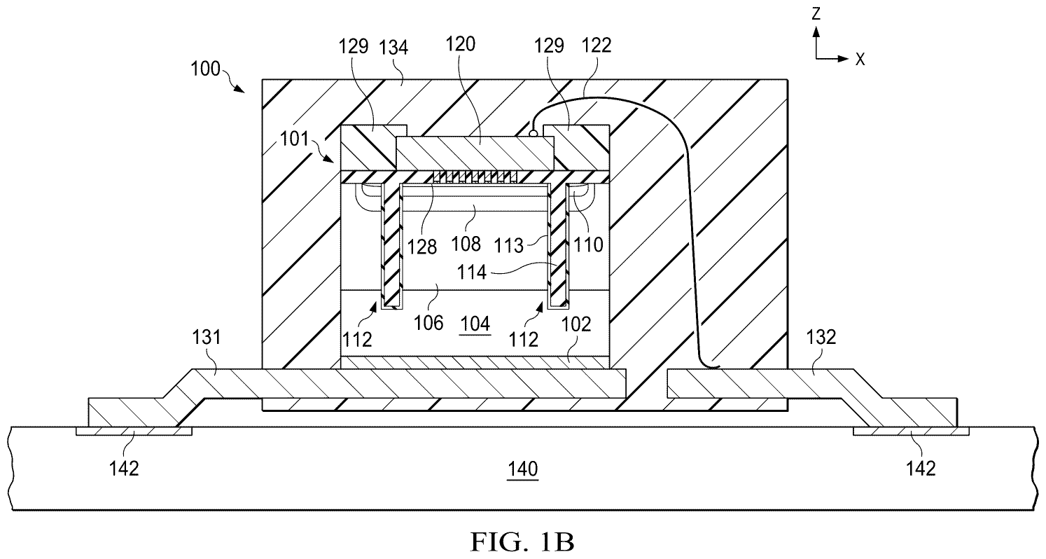

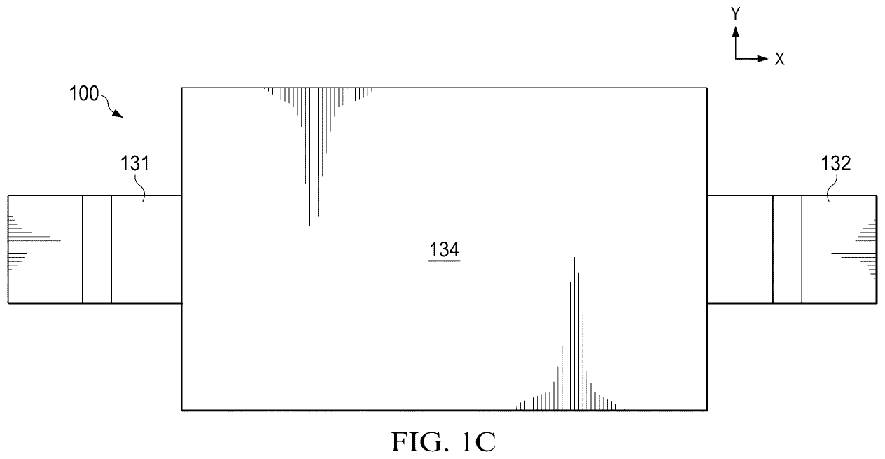

FIGS. 1-1C show a semiconductor device 100 with a vertical diode (e.g., schematically labeled “D” in FIG. 1) with a deep trench isolation structure for improved breakdown voltage performance. FIG. 1 shows a partial sectional side elevation view of the semiconductor device 100 taken along line 1-1 of FIG. 1A and FIG. 1A shows a partial sectional top plan view of the semiconductor device 100 taken along line 1A-1A a of FIG. 1. FIG. 1B shows a partial sectional side elevation view of a system with the semiconductor device 100 mounted to a circuit board, and FIG. 1C shows a top view of a small outline diode (SOD) implementation of the semiconductor device 100.

The device 100 is illustrated in an example three-dimensional space with a first direction X (FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. As shown in FIG. 1, the example semiconductor device 100 includes a semiconductor die 101 with a bottom metal first terminal 102 and a semiconductor substrate 104 over and contacting the first terminal 102. The semiconductor substrate 104 in one example is a silicon substrate with N-type majority carriers or dopants (e.g., phosphorus) and the substrate 104 is electrically connected to the first terminal 102. In one example, the substrate 104 is heavily doped (e.g., greater than approximately 1×10¹⁸ cm⁻³) to achieve high electrical conductivity (e.g., labeled “N+” in FIG. 1). In other examples different dopant levels can be used.

The semiconductor device 100 has a semiconductor layer 106 over the semiconductor substrate 104 with a thickness 107 along the third direction Z. The semiconductor substrate 104 in one example includes a separated portion of a base silicon or silicon-on-insulator (SOI) starting wafer. In one example, the semiconductor layer 106 is or includes epitaxial silicon with N-type majority carriers or dopants (e.g., phosphorus). The semiconductor layer 106 has respective adjacent first and second portions 110 and 108. The first portion 110 of the semiconductor layer 106 has a first conductivity type (e.g., P-type) and includes a first node (e.g., an anode) of the diode D. The second portion 108 of the semiconductor layer 106 has a second, opposite, conductivity type (e.g., N-type) and includes a second node (e.g., cathode) of the diode D. The second portion 108 extends into the semiconductor layer 106 along the third direction Z (e.g., downward in FIG. 1) to a first distance 109. Conductive metal silicide structures 111 provide electrical contact connection to the first portion 110 along the top side of the semiconductor layer 106.

The semiconductor device 100 includes an isolation trench 112 that extends through the first and second portions of the semiconductor layer 106 along the third direction Z (e.g., downward in FIG. 1 and into the page in the top view of FIG. 1A). The isolation trench 112 is an electrical isolator that defines an interior portion within the perimeter of the isolation trench 112 and separates the interior portion from an exterior portion outside the trench perimeter. The isolation trench 112 laterally surrounds the separated interior portions of the first and second portions 110 and 108 within the trench to form an anode and a cathode of the diode D. In one example, the diode D is a junction diode and the interior portions of the first portion 110 and the second portion 108 form the diode D. In another example, the interior portions of the first portion 110 and the second portion 108 form a Zener diode D that is laterally surrounded by the isolation trench 112.

A junction between the first portion 110 and the second portion 108 within the lateral extent of the isolation trench 112 is approximately planar and extends in a plane of the first and second directions X and Y. The isolation trench 112 extends into the semiconductor layer 106 along the third direction Z below the first portion 110 (e.g., anode) and below the second portion 108 (e.g., cathode) of the semiconductor layer 106. The isolation trench 112 in one example has a trench liner layer 113 and a fill material 114 and extends to a trench depth 115 as shown in FIG. 1. The trench liner 113 in one example is a single layer or a bilayer dielectric liner that can be or include thermally grown silicon dioxide (SiO₂) of any suitable stoichiometry and thickness. The isolation trench 112 in one example has a trench liner layer 113 and a fill material 114. The fill material 114 in one example is or includes a dielectric material, such as deposited silicon dioxide (SiO₂) of any suitable stoichiometry. In other examples, a different fill material can be used, such as SiO₂ and poly-silicon, with or without a single or multilayer liner (not shown).

The semiconductor device 100 also includes a dielectric layer 116, such as a pre-metal dielectric (PMD) that is or includes silicon dioxide. In one example, the dielectric layer 116 is contiguous with the dielectric fill material 114 and the trench 112, and the fill material 114 and the PMD dielectric layer 116 can be formed by a single deposition process, for example, followed by planarization using chemical mechanical polishing (CMP) or other suitable process to fill the trench 112 and set the final height of the dielectric layer 116.

Conductive metal contacts 118 extend along the third direction Z from the metal silicide structures 111 to provide electrical connection to the first portion 110 through the PMD dielectric layer 116. In one example, the metal contacts 118 are or include tungsten or other suitable conductive metal. The example semiconductor device 100 also includes a conductive metal terminal 120 over and contacting the top sides of the conductive metal contacts 118 to form a second terminal that is electrically connected to the first portion 110 within the interior defined by the trench 112 to provide an anode terminal connection of the diode D. In the illustrated example, the second terminal 120 is connected to a bond wire 122.

As further shown in FIGS. 1 and 1A, the isolation trench 112 is spaced laterally inward from lateral ends of the first portion 110 and the second portion 108 along both the first and second directions X (FIGS. 1 and 1A) and Y (FIG. 1) by a distance 124 that is greater than or equal to a lateral width 126 of the isolation trench 112 (e.g., along the first direction in the sectional view of FIG. 1, and along the first and second directions X and Y as shown in FIG. 1A. In one example, the isolation trench 112 is spaced laterally inward from a lateral end of the second portion 108 by a distance 127 that is greater than or equal to the lateral width 126 of the isolation trench 112 as further shown in FIGS. 1 and 1A.

In one example, the first portion 110 includes a shallow, more heavily p-doped third portion 128 that extends part way from the top side of the semiconductor layer 106 and downward into an upper portion of the first portion 110 along the third direction Z. In another implementation, the p-doped third portion 128 can be omitted. In one example, the semiconductor die 101 has a protective overcoat (PO) layer 129 that covers an upper side of the PMD 116 and exposes at least a portion of the top side of the second terminal 120. In another example, the PO layer 129 can be omitted.

The isolation trench structure 112 can have a tapered shape that is narrow at the bottom and wider at the top side of the semiconductor layer 106, for example, based on a trench etch process used to form the trench prior to sidewall dielectric formation and trench filling. The lateral trench width 126 of a tapered trench shape is determined at the widest part of the trench 112 (e.g., at the top side of the semiconductor layer 106). In the illustrated example, the first portion 110 extends into the top side of the semiconductor layer 106 by a second distance 125 that is less than the first distance 109. Although the trench 112 and other features are shown in FIGS. 1-1B as having sharp corners, other examples may include more rounded or radiused corners and other structures features and attributes.

As shown in FIGS. 1 and 1B, the bottom or first terminal 102 (e.g., cathode connection) is mechanically and electrically connected to a first conductive metal lead 131, for example, by soldering, conductive adhesive, etc. (not shown). The top or second terminal 120 (e.g., anode connection) is coupled to a second conductive metal lead 132 of the electronic device 100 by the bond wire 122. The first terminal 102 is electrically connected to the second portion 108 and the second terminal 118, 120 is electrically connected to the first portion 110. The first terminal 102 extends along the bottom side of the semiconductor substrate 104 and bottom side faces away from the semiconductor layer 106. The second terminal 118, 120 is located above the semiconductor layer 106.

The semiconductor device 100 in this example also includes a package structure 134, such as a mold compound material or ceramic package structure. The illustrated example includes a molded plastic package structure 134 that encloses the semiconductor die 101, the bond wire 122 and interior portions of the first and second conductive metal leads 131 and 132 and exposes outer portions of the leads 131 and 132 to allow soldering to corresponding conductive features 142 (e.g., landing pads) of a host circuit board 140 in a given system as shown in FIG. 1B.

As further illustrated in FIG. 1C, the illustrated example semiconductor device 100 has a 2-lead small outline diode (SOD) package with gullwing leads 131 and 132 extending outside opposite lateral ends of the molded package structure 134 to allow surface mount soldering to a host circuit board (FIG. 1B) or insertion into a socket (not shown) of a host system. In another example, the electronic device can have a different package shape, such as a surface mount dual flat no lead (DFN) package with two leads, a quad flat no lead (QFN) package with leads along four lateral sides, or other suitable package type and shape In other examples, different configurations are possible in other packages with appropriate changes in silicon die layout, for example small outline transistor (SOT) packages with three pins (e.g., Zener diodes in SOT-23 or SC-70), with two pins connected to the diode and one no-connect pin, as well as other package forms such as two separate Zener diodes connected in either common cathode or common anode fashion.

In other examples, the semiconductor device 100 can be an integrated circuit having two or more electronic components with one or more semiconductor dies 101 and suitable electrical interconnections between components and externally accessible conductive leads, where the diode D can have one or more terminals connected to device leads or the diode D can be interconnected to other circuit nodes in the device 100 without external lead connections.

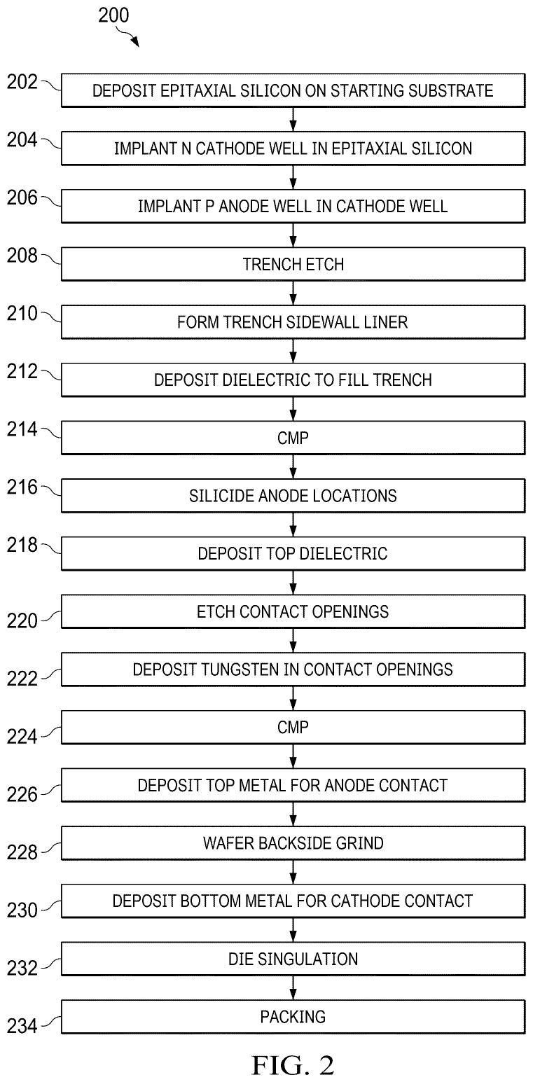

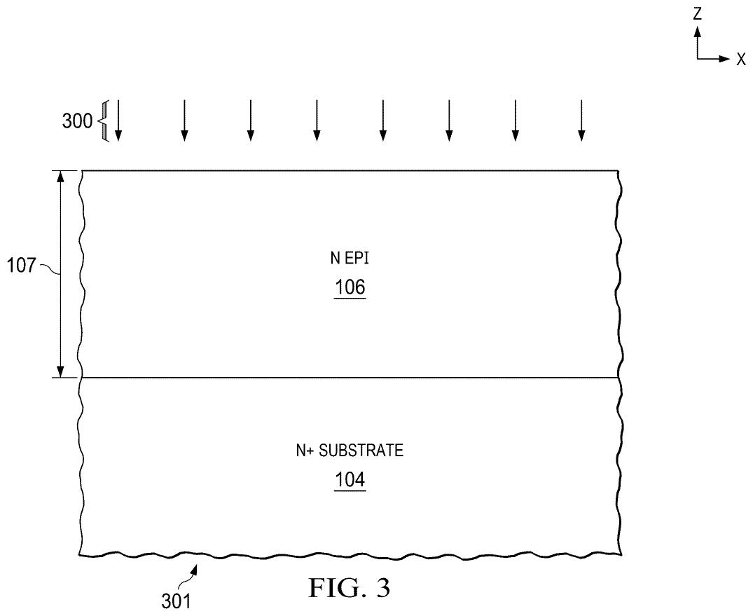

Referring also to FIGS. 2-14, FIG. 2 shows a method 200 of fabricating a semiconductor device, and FIGS. 3-14 show partial sectional side views of the semiconductor device 100 undergoing fabrication processing according to the method 200. The method 200 is illustrated and described in connection with initial processing of multiple unit areas of a starting wafer (e.g., labeled 301 in FIGS. 3-14), with each unit area corresponding to a prospective finished semiconductor die.

At 202 in FIG. 2, a semiconductor layer is formed on a starting wafer substrate having N-type dopants (e.g., phosphorus, etc.). The semiconductor substrate 102 (e.g., labeled “N+ SUBSTRATE” in FIG. 3) in one example includes a base silicon wafer with an N-type epitaxial silicon semiconductor layer 106 formed thereon (e.g., labeled “N EPI” in FIG. 3). In one example, the semiconductor layer 106 is an N-type epitaxial silicon layer formed over the semiconductor substrate 104. FIG. 3 shows one example, in which an epitaxial growth process 300 is performed with in-situ N-type dopants that grows the N-doped epitaxial silicon semiconductor layer 106 to the thickness 107 on the top side of the semiconductor substrate 104 of a starting silicon or SOI wafer 301. In one example, the process 300 forms the N-doped epitaxial silicon semiconductor layer 106 to a thickness 107 of approximately 3 to 20 μm with arsenic (As), phosphorus (P) and/or antimony (Sb) dopants with a dose of 1×10¹³ to 1×10¹⁸ cm⁻².

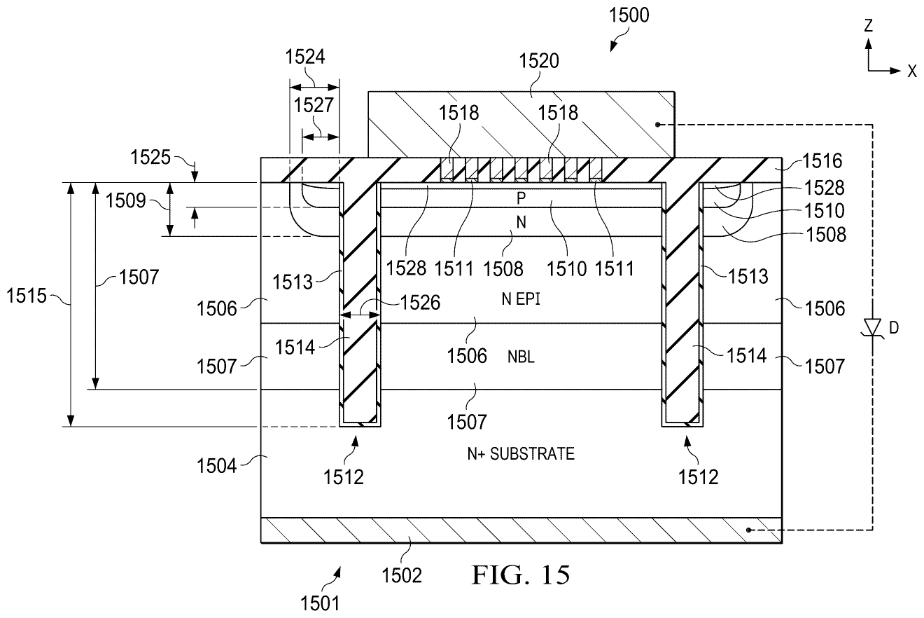

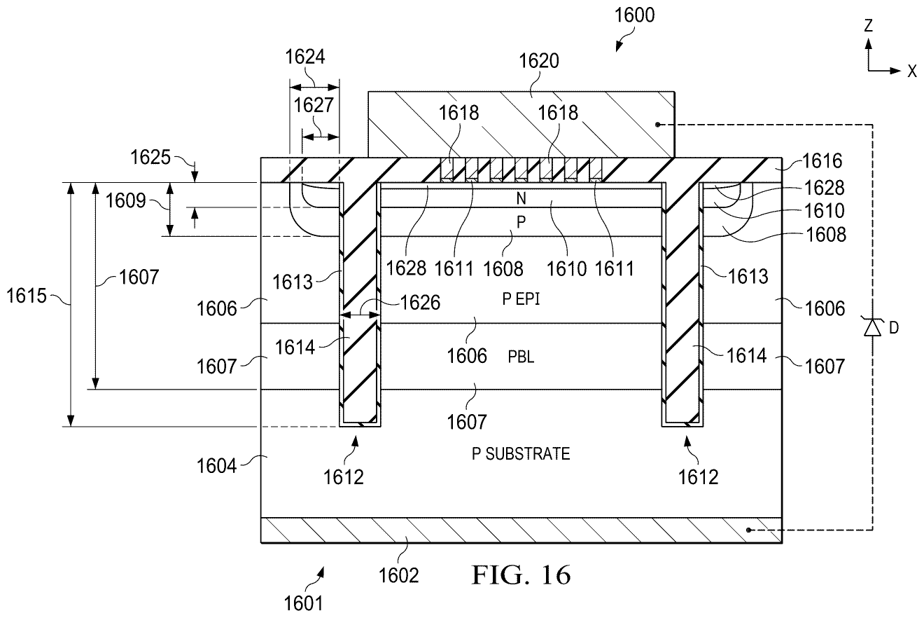

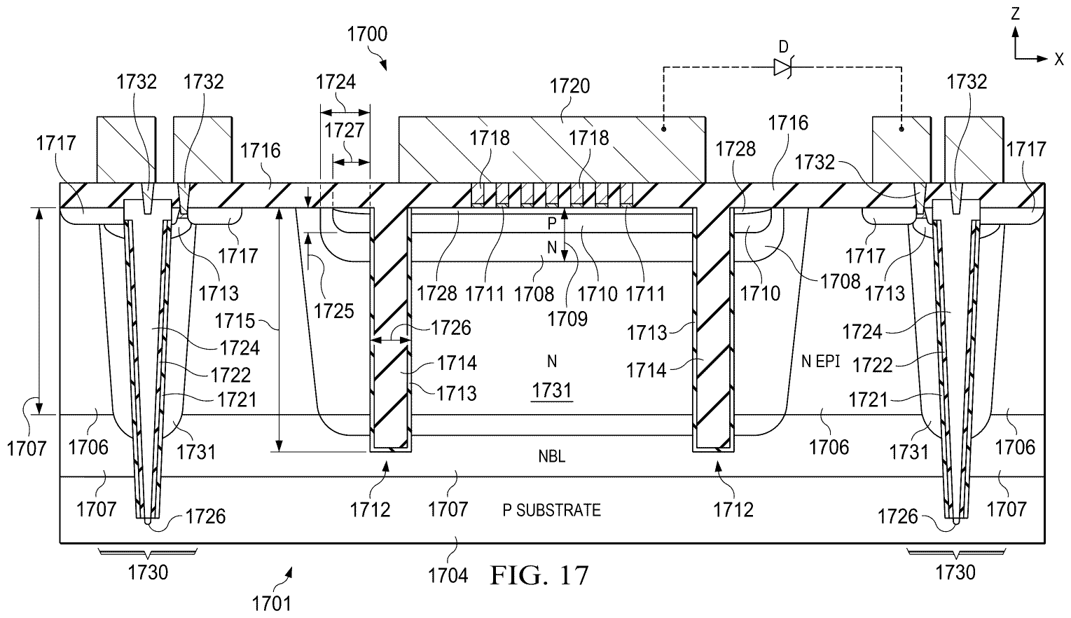

The starting wafer 301 has an initial thickness (e.g., along the third direction Z), and is processed at the starting thickness until a wafer backside grinding (e.g., at 228 in FIG. 2) prior to forming the lower or first metal contact for the cathode connection. In certain examples, one or more buried layers (not shown) can be implanted in the epitaxially grown silicon semiconductor layer 106 (e.g., an N-type buried layer or NBL as illustrated and described below in connection with FIGS. 15 and 17, or a P-type buried layer or PBL in FIG. 16 below).

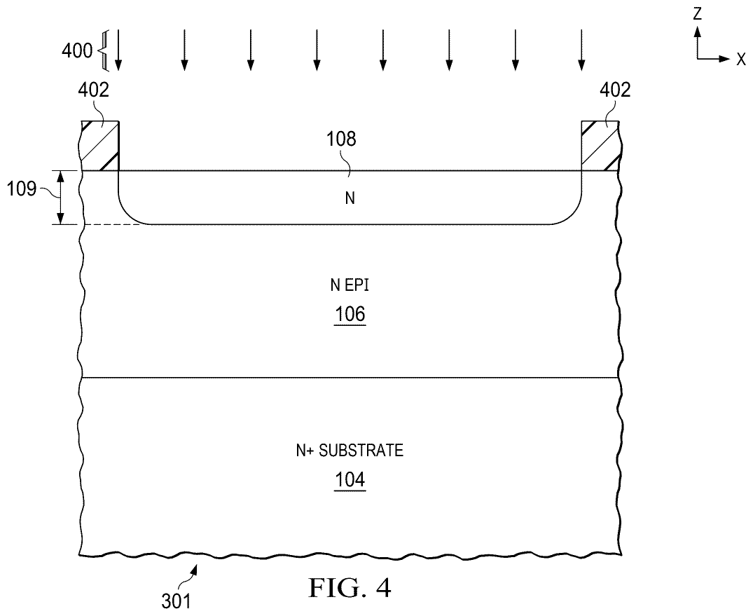

The method 200 continues in one example with optionally forming an N-type cathode well in the second region 108 of the semiconductor layer 106 at 204 in FIG. 2. In another example, the cathode well formation at 204 can be omitted, and a p-n junction of the diode is formed between the layers 106 and 110. FIG. 4 shows one example, in which an implantation process 400 is performed using N-type dopants (e.g., phosphorus, etc.) using an implant mask 402. The implantation process 400 implants the N-type dopants in the second portion 108 of the semiconductor layer 106 to the first distance 109 (e.g., the depth along the third direction Z) as shown in FIG. 4. In one example, the implantation process 400 implants arsenic (As), phosphorus (P) and/or antimony (Sb) with a dose of 1×10¹¹ to 1×10¹⁶ cm⁻², or combinations thereof. In this or another example, the N-type implantation 400 may be performed without a mask, and the second region 108 may extend across the entire starting wafer 301.

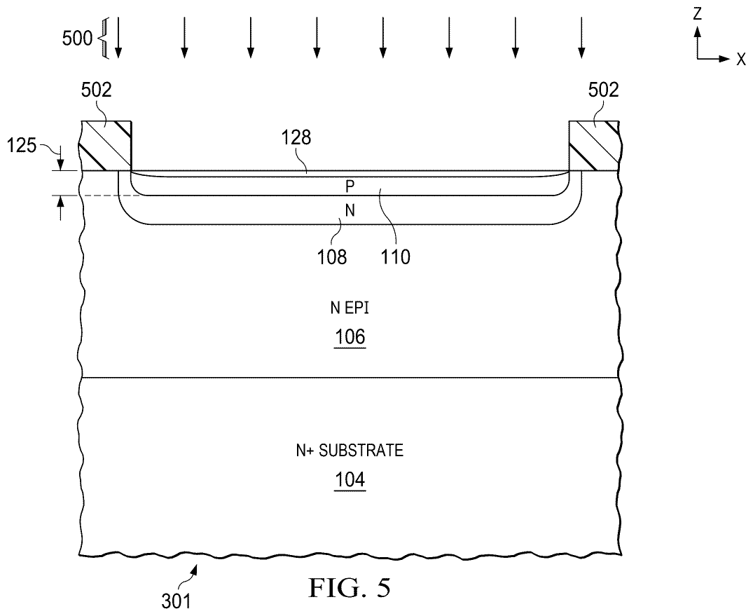

At 206 in FIG. 2, the method 200 continues with forming the P-type well in the first region 110 of the semiconductor layer 106. FIG. 5 shows one example, in which an implantation process 500 is performed using an implant mask 502. The process 500 implants boron or other P-type dopants into the first region 110 to the second distance 125 (e.g., the depth along the third direction Z), where the second distance 125 is less than the first distance 109. In one example, the implantation process 500 is a first implant (e.g., a P-type implant) that implants boron at a dose of 1×10¹¹ to 1×10¹⁶ cm⁻². As shown in FIG. 5, the first and second implanted portions 108 and 110 are adjacent to one another, with the second portion 110 including majority carriers of the first type (P-type). The implanted portions 108 and 110 after the process 500 form a p-n junction that has curved edges as shown in FIG. 5.

In one example, the processing at 206 in FIG. 2 (e.g., process 500 in FIG. 5) includes a second P-type dopant implantation with a higher dose and lower implant energy to form the more heavily p-doped third portion 128 that extends part way from the top side of the semiconductor layer 106 and downward into an upper portion of the first portion 110 along the third direction Z. In one example, the implantation process 500 includes the second P-type dopant implantation (e.g., a P+ implant) that implants boron at a dose of 1×10¹⁵ to 1×10¹⁶ cm⁻².

The method 200 in FIG. 2 continues at 208-214 with forming the isolation trench 112 that extends through the first and second portions 110, 108 of the semiconductor layer 106 and laterally surrounds interior portions of the first and second portions 110, 108 of the semiconductor layer 106 to form a junction between the interior portions of the first and second portions 110, 108 within the isolation trench 112 that is approximately planar.

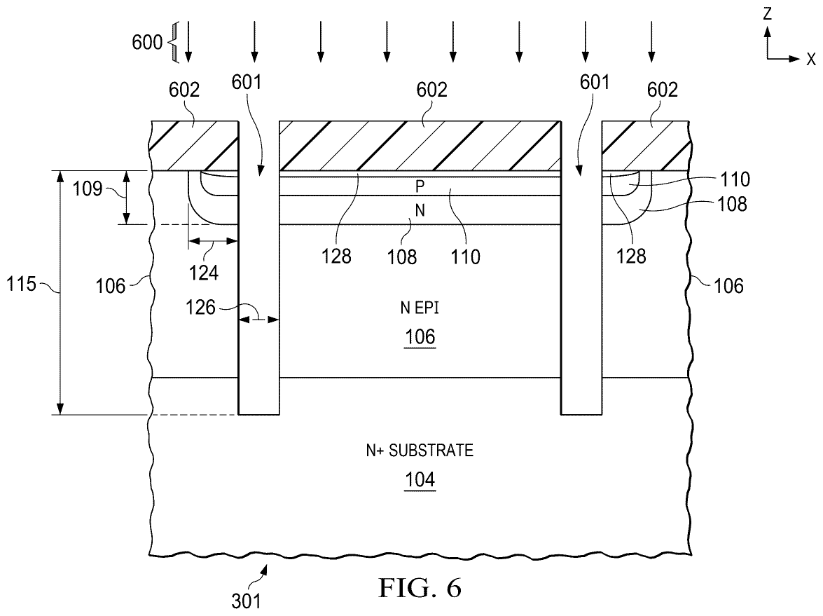

The trench formation begins at 208 with etching a trench. FIG. 6 shows one example, in which an etch process 600 is performed using a patterned etch mask 602. In one example, the trench etch process 600 etches a trench 601 through the first and second portions 110 and 108 of the semiconductor layer 106 through the opening in the etch mask 602 to form an encircling trench 601 that laterally surrounds interior (e.g., laterally encircled or surrounded) portions of the first and second portions 110 and 108 of the semiconductor layer 106, which forms an anode and a cathode of the diode D.

In various implementations, the trench 601 extends through both the first and second portions 110 and 108, and the trench depth 115 extends below the bottom of the second portion 108. In the illustrated example, the trench 601 extends through the semiconductor layer 106 and partially into the substrate 104 to the depth 115. In another example, the trench 601 can extend into a buried conductive layer of the semiconductor layer 106 (e.g., NBL or PBL of FIGS. 15-17 below). Any suitable trench etch process 600 and etch mask 602 can be used, including single or multistep etching using one or more suitable masks.

The openings in the trench etch mask 602 set the lateral position of the trench 601 and the trench width 126 (e.g., as shown in FIG. 6 and in FIG. 1A above). The formation of the trench 601 divides the first and second portions 110 and 108 into interior and exterior portions, with the interior portion of the junction between the first and second regions 110 and 108 forming a p-n junction that is substantially planar within the interior of the trench 601. The resulting diode D (e.g., FIG. 1 above) benefits from the planar junction with respect to enhanced control of breakdown voltage and other performance parameters of a junction diode or Zener diode in operation of the semiconductor device 100. The use of the isolation trench 112 provides an approximately planar diode junction and the diode breakdown voltage performance in certain examples is very close to parallel-plane breakdown voltage limit. Moreover, the isolation trench 112 allows compact designs with significantly smaller area (e.g., the trench width 126 at the widest point at or near the top side of the semiconductor layer 106 can be 1 to 5 μm, such as approximately 2.0 μm in one example) without adding area for floating field rings and/or field plates. In this or another example, the etch process 600 forms the trench 601 to a trench depth 115 of approximately 3 to 20 μm.

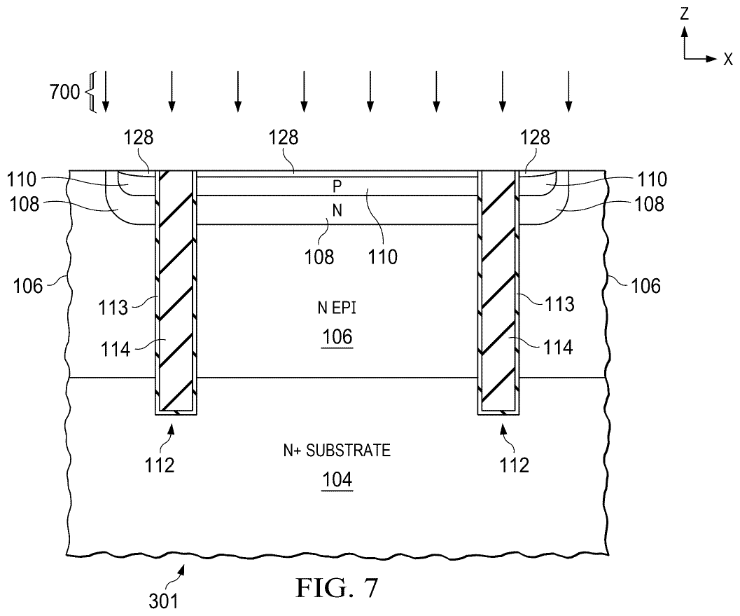

The trench 601 is then filled at 210 and 212 in FIG. 2. At 210, the trench sidewall liner 113 is formed. FIG. 7 shows one example, in which a trench fill process 700 is performed that forms a single or multilayer trench liner 113 along the sidewalls and bottom of the trench 601 and fills the trenches 601 with dielectric material, such as silicon dioxide. The process 700 in one example includes thermal growth process in a furnace with an oxidizing interior environment using an O₂ source stream at a suitable temperature to deposit or grow a silicon dioxide trench liner layer 113 to any suitable desired thickness along the sidewalls and bottom of the trench 601. The method 200 continues at 212 with depositing further dielectric material 114 to fill the trenches 601. In one example, the trench fill process 700 includes a chemical vapor deposition process that fills the trench 601 with silicon dioxide material 114 as shown in FIG. 7. In one example, the deposited silicon dioxide extends over the top side of the semiconductor layer 106 and the fill process 700 also includes a chemical mechanical polishing (CMP) step or other planarization processing that removes any deposited dielectric from the top side of the semiconductor layer 106 and provides a substantially planar top side surface.

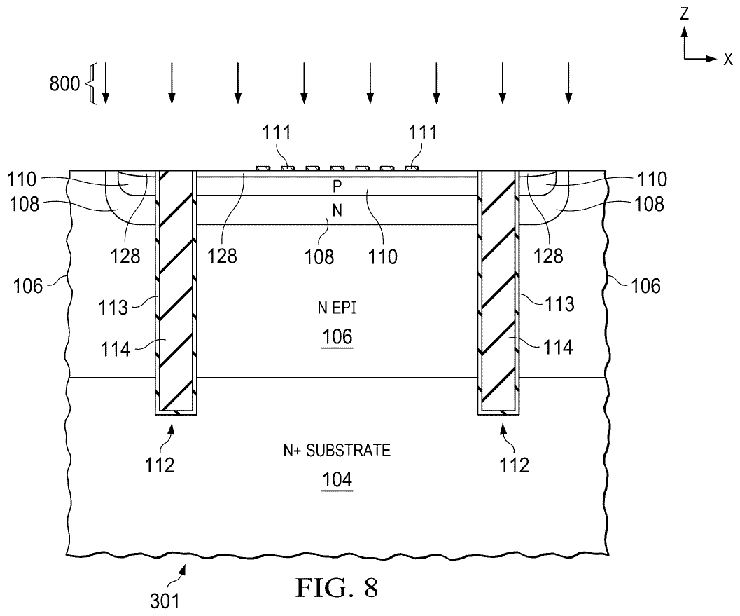

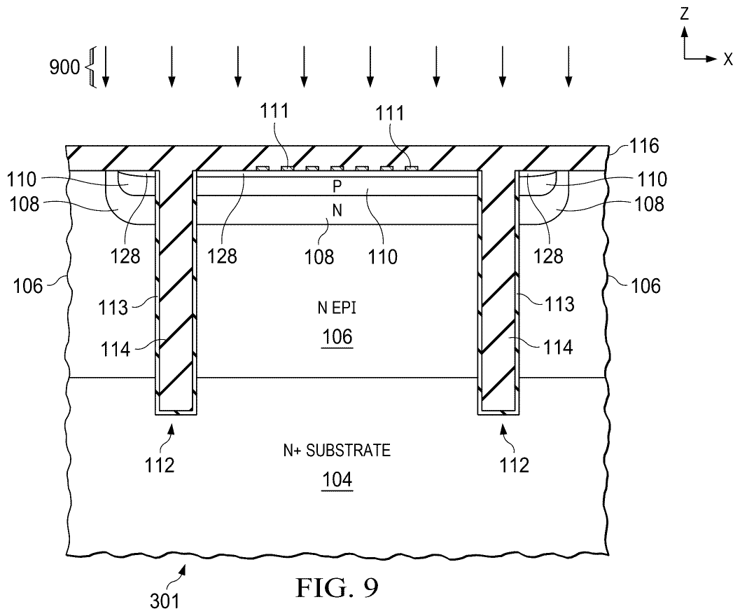

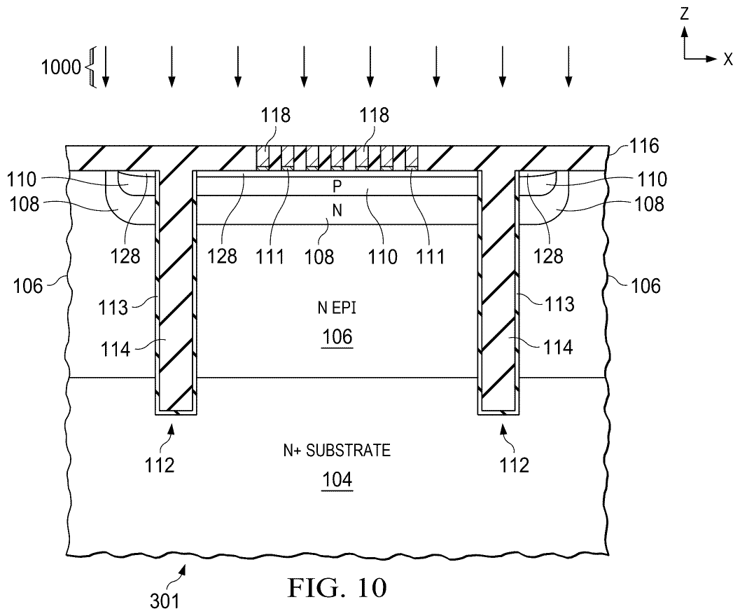

The method 200 continues at 216 in FIG. 2 with silicide processing. FIG. 8 shows one example, in which a silicidation process 800 is performed that forms the metal silicide structures 111 providing electrical connection to the first portion 110 along the top side of the semiconductor layer 106—e.g., using silicide block structures (not shown). At 218 in FIG. 2, a pre metal dielectric (PMD) or top dielectric 116 is formed, FIG. 9 shows one example in which a deposition process 900 is performed that deposits the PMD dielectric layer 116 (e.g., silicon dioxide) on the top side of the semiconductor layer 106 and over the top of the trench dielectric liner and fill materials 113 and 114. Contact openings are etched through the PMD dielectric layer 116 at 218 in FIG. 2, and tungsten or other conductive metal is deposited at 222 to fill the contact openings. The top side of the PMD is then planarized at 224, such as by chemical mechanical polishing (CMP). FIG. 10 shows one example, in which metallization processing 1000 has been performed to form the contact openings, form the tungsten contacts 118 in the openings, planarize the top side, and form any included protective overcoat (PO) layer 129 over the upper side of the PMD 116 and exposing at least a portion of the top side of the second terminal 120.

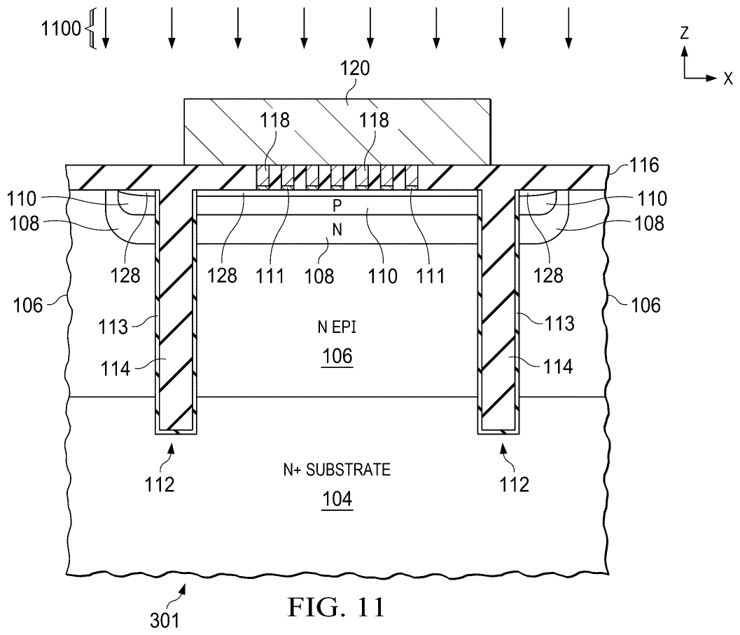

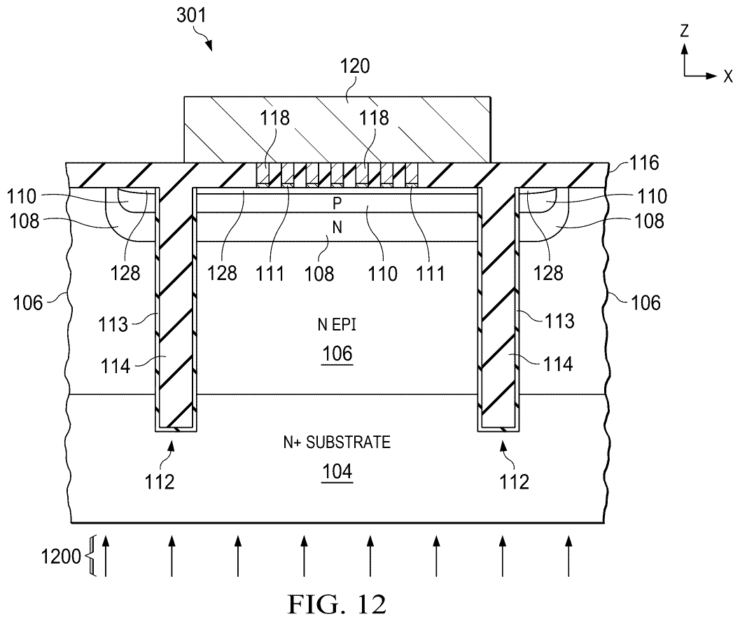

The method 200 continues at 226 in FIG. 2 with anode contact formation. FIG. 11 shows one example, in which a deposition process 1100 is performed that forms the top side second contact 120 of conductive metal (e.g., copper, aluminum, etc.). In one example, the wafer back side (e.g., the bottom side in the orientation of FIG. 12) is ground at 228 in FIG. 2. FIG. 12 shows one example, in which a back grind process 1200 is performed that removes material from the starting bottom side of the substrate 104. In another example, the silicide structures 111 and the tungsten contacts 118 can be omitted and the top metal can be directly deposited on the silicon exposed through the contact openings in the PMD dielectric layer 116 after the openings have been etched at 220.

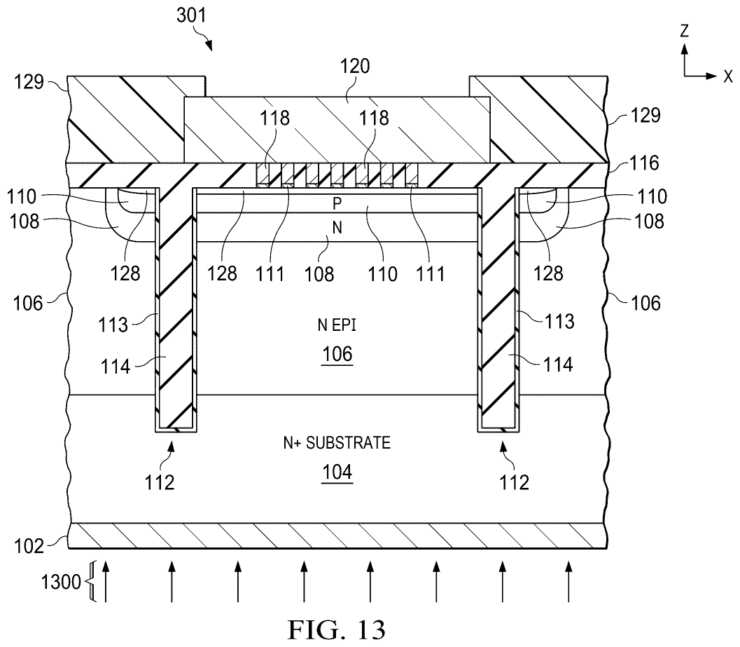

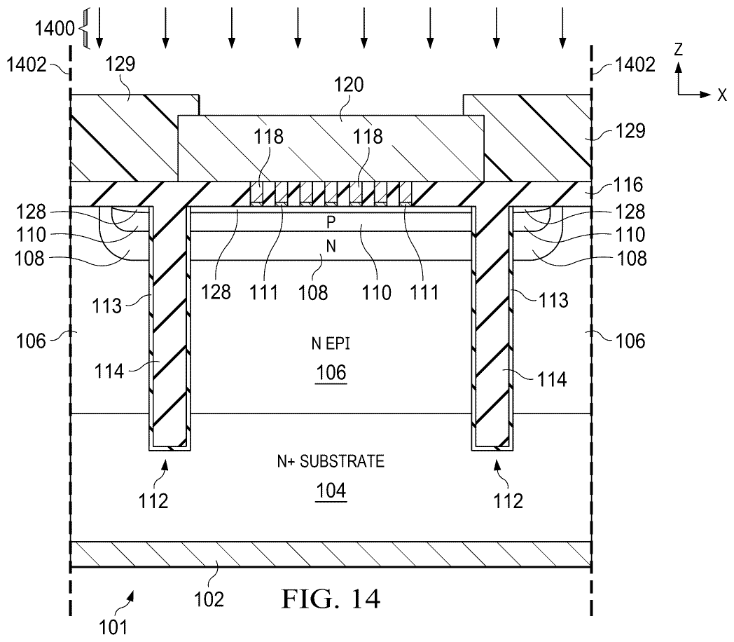

At 230 in FIG. 2, the bottom side or first metal contact is formed for cathode connection. FIG. 13 shows one example, in which a back side metallization process 1300 is performed that forms the bottom metal first terminal 102 on the bottom side of the substrate 104 (e.g., ground), for example, by plating or other deposition of a conductive metal such as copper, aluminum, silver, etc. The method 200 continues at 232 in FIG. 2 with die singulation or separation to separate individual semiconductor dies (e.g., die 101 in FIGS. 1 and 1A above) from the processed wafer 301. FIG. 14 shows one example, in which a die singulation process 1400 is performed using any suitable technique and equipment (e.g., saw cutting, laser cutting, etc.) that separates the illustrated semiconductor die 101 from the processed wafer structure along cut lines 1402.

The method 200 continues in one example with packaging operations at 234 in FIG. 2. In one example, the packaging at 234 proceeds with a starting lead frame panel array with rows and columns of unit areas, each corresponding to a prospective packaged electronic device 100 as shown in FIGS. 1-1B above. The packaging at 234 in one example includes die attach processing to attach the bottom side of the metal first terminal 102 to a conductive metal feature such as the first lead 131 in FIG. 1 by soldering or conductive epoxy adhesive, as well as wirebonding to connect the second terminal 120 to the second lead 132 via the bond wire 122, molding to form the molded package structure 134, and package separation to trim the leads 131 and 132 and separate individual packaged semiconductor device 100 from the starting panel array structure.

The electronic device 100 provides advantages with respect to compact size and small diode are without diode breakdown voltage reduction compared to implanted anode and cathode (p and n) regions having curved or radiused junction corners at the edges of implant boundaries. These breakdown voltage performance advantages can be achieved, moreover, without the significant area and size increases associated with floating field rings and/or field plates above the curved edges of the implanted regions. The electronic device 100 has a planar p-n junction surrounded by the isolation trench 112. The isolation trench 112 helps provide a planar junction without the adverse effects of curved or radiused diffusion region of p-n junction diodes or Zener diodes in a compact form that facilitates the ability to reduced device size and increase power density, etc. In certain examples, the upper contacts 118 are formed only within the lateral boundary of the isolation trench 112 and the remaining portions of the first and second regions 110 and 108 are not connected such that the rounded or curved edges do not impact the electrical performance of the diode D.

The diode D can be implemented in a standalone diode device (e.g., the example 2 terminal SOD device 100 of FIGS. 1-1B above) or can be incorporated into different package formats and/or in an integrated circuit with other electronic components. Integrated circuit examples (e.g., FIG. 17 below) can incorporate the diode isolation trench 112 as part of a deep trench isolation process used for isolation trenches elsewhere in a given device design without increasing manufacturing cost or complexity, and incorporation into new standalone diode device or IC designs can incorporate the diode isolation trench 112 with an additional mask while helping to provide a compact design for improved power density and reduced device size in a variety of different device package, for example, small outline transistor (SOT), small outline diode (SOD), dual or quad flat no-lead (DFN, QFN) component or device packages, etc.

FIGS. 15-18A show further non-limiting example electronic device implementations with integrated diodes with planar p-n junctions surrounded by an isolation trench. FIG. 15 shows a partial sectional side view of another semiconductor device 1500 having oppositely doped implanted regions and a trench 1512 surrounding an anode and a cathode of a vertical diode D with a planar junction. The semiconductor device 1500 in one example has structures, features, materials, and dimensions 1501, 1502, 1504, 1506, 1508-1516, 1518, 1520, and 1524-1528 that are the same or equivalent to the structures, features, materials, and dimensions 101, 102, 104, 106, 108-116, 118, 120, and 124-128 as described above in connection with FIGS. 1-1B unless otherwise indicated. As shown in FIG. 15, the semiconductor device 1500 has a top side anode connection, a bottom side cathode connection and an N-type buried layer 1507 (e.g., labeled “NBL”) in a semiconductor layer 1506 over a semiconductor substrate 1504, with an isolation trench 1512 that extends through the first and second portions 1510 and 1508 of the semiconductor layer 1506, into the buried layer 1507 for improved breakdown voltage performance.

FIG. 16 shows a partial sectional side view of another semiconductor device 1600 having oppositely doped implanted regions and a trench 1612 surrounding an anode and a cathode of a vertical diode D with a planar junction. The semiconductor device 1600 in one example has structures, features, materials, and dimensions 1601, 1602, 1604, 1606, 1608-1616, 1618, 1620, and 1624-1628 that are the same or equivalent to the structures, features, materials, and dimensions 101, 102, 104, 106, 108-116, 118, 120, and 124-128 as described above in connection with FIGS. 1-1B, with opposite dopant types to form the diode D with a top side connection to the cathode and a bottom side anode connection. In one example, the substrate 1604 has P-type dopants (e.g., labeled “P SUBSTRATE” in FIG. 16) and can be heavily doped (e.g., greater than approximately 1×10¹⁸ cm⁻³) to achieve high electrical conductivity. In other examples different dopant levels can be used. The semiconductor device 1600 includes a first terminal 1602 that is electrically connected to the anode in the interior portion of the P-type second portion 1608 of the semiconductor layer 1606, and a second terminal 1618, 1620 electrically connected to the cathode of the first portion 1610 in the interior portion laterally surrounded by the isolation trench 1612. The N-type first portion 1610 extends into a side of the semiconductor layer 1606 by a first distance 1625 and the second portion 1608 extends into the top side of the semiconductor layer 1606 by a second distance 1609 that is greater than the first distance 1625. As shown in FIG. 16, the semiconductor device 1600 has a P-type buried layer 1607 (e.g., labeled “PBL” in a P-type epitaxial semiconductor layer 1606 over a P-type semiconductor substrate 1604. In addition, the semiconductor device 1600 has an isolation trench 1612 that extends through the first and second portions 1610 and 1608 of the semiconductor layer 1606, into and through the buried layer 1607 and into the substrate 1604 for improved breakdown voltage performance.

FIG. 17 shows a partial sectional side view of an integrated circuit semiconductor device 1700 with oppositely doped first and second portions 1710 and 1708 of a semiconductor layer 1706, and a trench 1217 surrounds interior portions of the first and second portions 1710 and 1708 to provide a diode with a planar junction, top side anode and cathode connections and a buried layer (NBL) 1707. The semiconductor device 1700 in one example has structures, features, materials, and dimensions 1701, 1702, 1704, 1706, 1708-1716, 1718, 1720, and 1724-1728 associated with the integrated diode D that are the same or equivalent to the structures, features, materials, and dimensions 101, 102, 104, 106, 108-116, 118, 120, and 124-128 as described above in connection with FIGS. 1-1B unless otherwise provided herein. In addition, the semiconductor device 1700 includes further electronic components (not shown, such as other diodes, transistors, capacitors, etc. to form an integrated circuit. The illustrated example includes a P-type substrate 1704 and an N-type epitaxial semiconductor layer (e.g., silicon) 1706 the N-type buried layer 1707 formed in a bottom portion of the semiconductor layer 1706. The illustrated example also includes further structures (e.g., shallow trench isolation or STI) 1717 and deep trench isolation features 1730 including deep trenches that extend through the semiconductor layer 1706 and the NBL 1707 into the substrate 1704. The deep trench isolation structures 1730 in the illustrated example are laterally surrounded by a deep N-type implanted well 1731 that extends downward to the buried layer 1707, and the deep trenches have first and second trench sidewall liner layers 1721 and 1722 with conductive doped polysilicon 1724 filling the deep trenches. A concurrently formed N-type deep well 1731 is formed in the diode region of the semiconductor device 1700 and extends downward into the buried layer 1707 and laterally surrounds upper portions of the isolation trench 1712 of the diode D. The deep N-type wells 1731 that surround the deep trench isolation structures include a top side contact 1732 to provide electrical connection to conductive features of the metallization structure, including providing a top side cathode connection for the diode D through a highly doped N-type implant 1713, the deep N-type well 1731 and the buried layer 1707 to connect the cathode of the diode D within the interior portion of the semiconductor layer 1706 laterally surrounded by the isolation trench 1712.

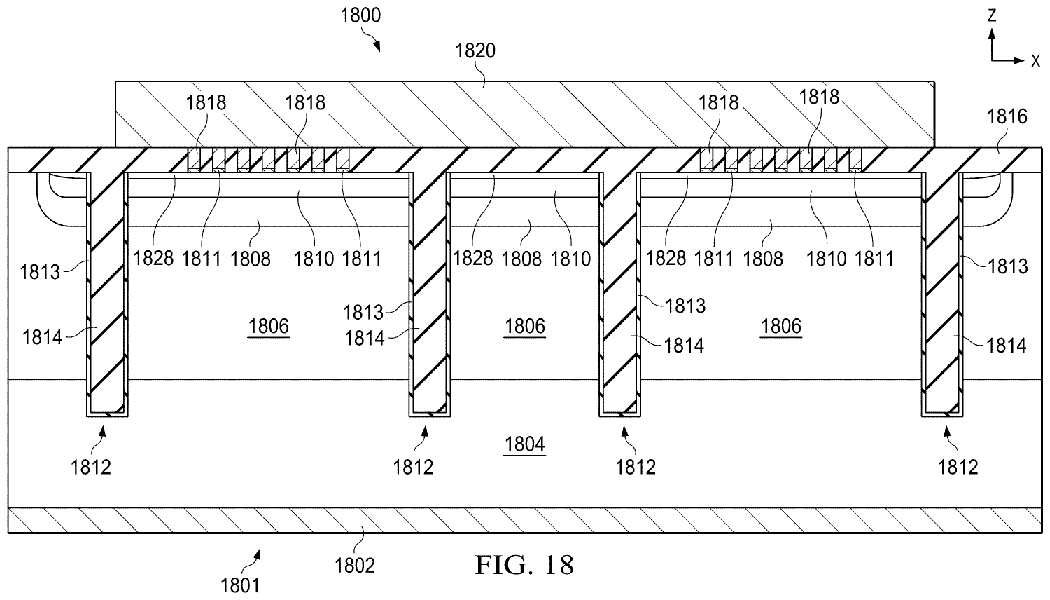

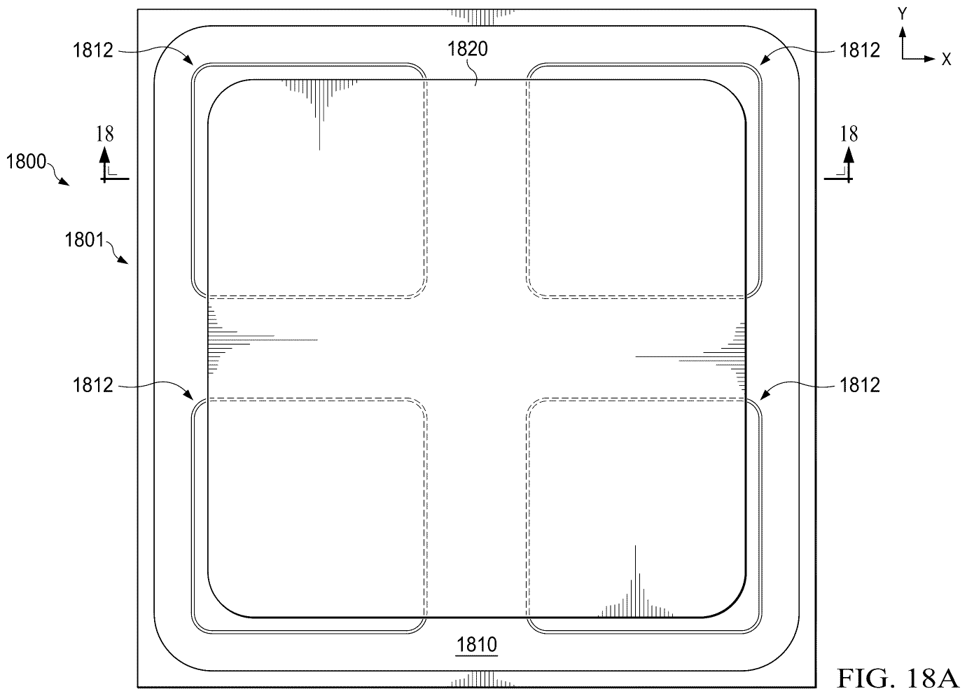

FIGS. 18 and 18A a show sectional side and top views of another semiconductor device 1800 with oppositely doped implanted portions and an array of isolation trenches 1812 surrounding respective portions and planar p-n junctions of a diode. The semiconductor device 1800 in one example has structures, features, materials, and dimensions 1801, 1802, 1804, 1806, 1808-1816, 1818, 1820, and 1824-1828 associated with the integrated diode D that are the same or equivalent to the structures, features, materials, and dimensions 101, 102, 104, 106, 108-116, 118, 120, and 124-128 as described above in connection with FIGS. 1-1B unless otherwise provided herein. In this example, the diode is formed using a 2×2 array of isolation trenches 1812 that surround respective interior portions of the first and second portions 1810, 1808 of the semiconductor layer 1806. Conductive metal (e.g., tungsten) contacts 1818 provide electrical connection via corresponding metal silicide structures 1811 to the interior portions of the first portion 1810 within the lateral boundary of each respective isolation trench 1812, and the lower or first terminal 1802 provides a unitary cathode connection for the diode. In this and other examples, the diode can be formed using one or more isolation trenches within a given semiconductor die, and there can be any combination of trenches within a semiconductor device, including arrays with rows and columns of trenches.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present invention should not be limited by any of the above described examples. Rather, the scope of the disclosure should be defined in accordance with the following claims and their equivalents. Modifications are possible in the described examples, and other implementations are possible. within the scope of the claims.

What is claimed is:

1. A semiconductor device, comprising:
a semiconductor layer over a semiconductor substrate and having adjacent first and second portions, the first portion of the semiconductor layer having a first conductivity type and including a first node, and the second portion of the semiconductor layer having a second, opposite, conductivity type and including a second node; and
an isolation trench extending through the first and second portions of the semiconductor layer and laterally surrounding the first node and the second node.

2. The semiconductor device of claim 1, wherein a junction between the first portion and the second portion within the isolation trench is approximately planar.

3. The semiconductor device of claim 1, wherein the isolation trench extends into the semiconductor substrate.

4. The semiconductor device of claim 1, wherein the isolation trench extends into the semiconductor layer below the first portion and the second portion.

5. The semiconductor device of claim 1, wherein the isolation trench is spaced laterally inward from a lateral end of the first portion by a distance that is greater than or equal to a lateral width of the isolation trench.

6. The semiconductor device of claim 1, wherein the isolation trench is spaced laterally inward from a lateral end of the second portion by a distance that is greater than or equal to a lateral width of the isolation trench.

7. The semiconductor device of claim 1, further comprising a buried conductive layer in the semiconductor layer over the semiconductor substrate, wherein the isolation trench extends into the buried conductive layer.

8. The semiconductor device of claim 1, wherein:
the second portion extends into the semiconductor layer by a first distance; and
the first portion extends into the semiconductor layer by a second distance that is less than the first distance.

9. The semiconductor device of claim 1, further comprising a first terminal electrically connected to the second portion and a second terminal electrically connected to the first portion, wherein:
the first terminal extends along a side of the semiconductor substrate, the side facing away from the semiconductor layer; and
the second terminal is located above the semiconductor layer.

10. The semiconductor device of claim 1, further comprising a first terminal electrically connected to the first portion and a second terminal electrically connected to the second portion, wherein:
the first portion extends into the semiconductor layer by a first distance; and
the second portion extends into the semiconductor layer by a second distance that is less than the first distance.

11. The semiconductor device of claim 10, wherein:
the first terminal extends along a side of the semiconductor substrate, the side facing away from the semiconductor layer; and
the second terminal is located above the semiconductor layer.

12. The semiconductor device of claim 1, further comprising a first terminal electrically connected to the first portion and a second terminal electrically connected to the second portion, wherein the first terminal extends along a side of the semiconductor substrate.

13. The semiconductor device of claim 1, wherein the first portion and the second portion form a Zener diode.

14. A system, comprising:
a circuit board having conductive features; and
a semiconductor device having a package structure, a semiconductor die enclosed by the package structure, and conductive leads partially enclosed by the package structure and soldered to respective ones of the conductive features of the circuit board, the semiconductor die comprising a semiconductor layer over a semiconductor substrate and having adjacent first and second portions, the first portion of the semiconductor layer having a first conductivity type and including a first node, and the second portion of the semiconductor layer having a second, opposite, conductivity type and including a second node, and an isolation trench extending through the first and second portions of the semiconductor layer and laterally surrounding the first node and the second node.

15. The system of claim 14, wherein a junction between the first portion and the second portion within the isolation trench is approximately planar.

16. The system of claim 14, wherein the isolation trench extends into the semiconductor substrate.

17. The system of claim 14, wherein the isolation trench extends into the semiconductor layer below the first portion and the second portion.

18. The system of claim 14, wherein the isolation trench is spaced laterally inward from a lateral end of the first portion by a distance that is greater than or equal to a lateral width of the isolation trench.

19. The system of claim 14, wherein the isolation trench is spaced laterally inward from a lateral end of the second portion by a distance that is greater than or equal to a lateral width of the isolation trench.

20. A method of fabricating a semiconductor device, the method of comprising:
implanting dopants of a first conductivity type in a first portion of a semiconductor layer;
implanting dopants of a second, opposite, conductivity type in a second portion of the semiconductor layer that is adjacent to the first portion; and
forming an isolation trench that extends through the first and second portions of the semiconductor layer and laterally surrounds interior portions of the first and second portions of the semiconductor layer to form a junction between the interior portions of the first and second portions within the isolation trench that is approximately planar.

21. The method of claim 20, wherein forming the isolation trench includes:
etching a trench through the first and second portions of the semiconductor layer; and
forming a dielectric material in the trench.

22. The method of claim 20, wherein the isolation trench is etched into a substrate below the semiconductor layer.

23. The method of claim 20, wherein the isolation trench is etched into a buried conductive layer in the semiconductor layer.
